(19) United States
(12) Patent Application Publication
(10) Pub. No.: US 2026/0266635 A1
(43) Pub. Date: Sep. 10, 2026

(54) HOUSING FOR AN AUTOMATION FIELD DEVICE

(71) Applicant: Endress+Hauser SE+Co. KG, Maulburg (DE)

(72) Inventors: Alexander Meinhardt, Lörrach (DE); Pascal Matt, Lörrach (DE); Daniel Kopp, Lörrach (DE); Martin Kropf, Steinen (DE)

(21) Appl. No.: 19/162,625

(22) PCT Filed: Jan. 29, 2024
(86) PCT No.: PCT/EP2024/052093

§ 371 Date: Sep. 5, 2025

(30) Foreign Application Priority Data
Mar. 7, 2023 (DE) 10 2023 105 619.0

(51) Int. Cl. G01D 11/26; H05K 5/06

(52) U.S. Cl. CPC G01D 11/26; H05K 5/061

(57) ABSTRACT

Housing comprising a housing body (1.4) and a housing lid (1.2), wherein the housing body (1.4) forms an inner space (1.3) accessible through an opening (1.6), and wherein the housing body (1.4) includes, adjoining the opening (1.6), an essentially cylindrical region (1.5), on which the housing lid (1.2) is placeable for closing the housing body (1.4),
wherein the housing body and the housing lid are matched to one another and formed in such a manner that the housing lid is pluggable, thus can be plugged, with the lid opening over the cylindrical region,
wherein the housing lid (1.2) and/or the cylindrical region (1.5) of the housing body have securement means (1.53),
wherein the housing lid (1.2) and/or the cylindrical region (1.5) of the housing body (1.4) have a lifting means (1.8), which is adapted at least when opening the housing lid (1.2) by the counterrotation movement (8) to guide the housing lid axially, such that at least a partial guided axial movement occurs during the counterrotation movement (8) when opening the housing lid (1.2) from the closed position.

The invention relates to a housing, especially to a field device housing, and to a field device of automation technology.

In automation technology, especially in process automation technology, field devices are often applied, which serve for determining, optimizing and/or influencing process variables. Serving for registering process variables are sensors, such as, for example, fill level measuring devices, flow measuring devices, pressure- and temperature measuring devices, conductivity measuring devices, etc., which register the corresponding process variables, fill level, flow, pressure, temperature, and conductivity. Serving for influencing process variables are actuators, such as, for example, valves or pumps, via which the flow of a liquid in a pipeline section, or the fill level in a container, can be changed. Referred to as field devices are, in principle, all devices, which are applied near to a process and which deliver, or process, process relevant information. In connection with the invention, the terminology, field device, refers, thus, also to remote I/Os, and, in general, devices, which are arranged at the field level. A large number of such field devices are manufactured and sold by the firm, Endress+Hauser.

Such field devices always have a field device housing composed of a housing body and a housing lid. Usually, the housing body is made of metal, especially sheet metal. There are, however, naturally, also other materials, of which the housing body can be made, e.g. plastic. For attaching the housing lid, at least in the case of metal housing body, a kind of “marmalade, jam, or jelly glass jar-” or “bayonet connection” is provided, in the case of which a plug-rotation movement of the housing lid relative to the housing body is performed, since, for manufacturing reasons, a metric screw thread cannot be directly provided in the sheet metal. Additionally, in order to assure a tight sealing of the housing lid, a peripheral sealing means is provided in an overlapping region, where the housing lid sits on the housing body. In such case, the housing lid is usually so embodied that a geometric-, or contour element of the lid compresses the peripheral sealing means between the housing body and the housing lid upon the attaching of the lid for closure of the housing. Axially sealing seals (axial seal seating) have, in such case, the disadvantage that the sealing means requires ever more torque as the housing lid is rotated further for closure. In such case, the sealing action is only reached after a difficultly defined rotational angle.

For this reason, the peripheral seal is frequently embodied as a radial seal seat. This seal design effects, however, no axial lifting of the lid during opening, such that in the case of radial seal seats the housing lid needs to be rotated with higher torque over a certain distance and supplementally the housing lid must be removed counter to the return force of the peripheral seal. Such can guide to tilting of the housing lid and, thus, to jamming, such that a more difficult opening of the housing is experienced.

An object of the invention is, thus, to provide a housing, especially a field device housing, which enables an easy opening and closing of the housing lid, without occurrence of jamming and/or damage.

The object is achieved according to the invention by the housing, especially the field device housing, as defined in claim 1 and by the field device of automation technology as defined in claim 10.

The housing, especially field device housing, of the invention comprises a housing body and a housing lid, wherein the housing body has a muglike shape with an opening and forms an inner space accessible through the opening, wherein the housing body is formed preferably of metal, especially preferably of a steel, and quite especially preferably a stainless steel, and wherein the housing body includes, adjoining the opening and defining the opening, an essentially cylindrical region, on which the housing lid is placeable for closing the housing body,
wherein the housing lid has a traylike shape with a lid floor and a lid opening,
wherein the housing lid is formed of metal, preferably a steel, especially preferably a stainless steel, and wherein the housing body and the housing lid are matched to one another and formed in such a manner that the housing lid is pluggable, thus can be plugged, with the lid opening over the cylindrical region,
wherein the housing lid and/or the cylindrical region of the housing body have securement means, which are embodied in such a manner that the housing lid can be brought by means of a rotational movement into a closed position on the housing body and can be locked by the securement means in the closed position and further can by a counterrotation movement be released from the closed position,
wherein the housing lid and/or the cylindrical region of the housing body have a lifting means, which is adapted at least when opening the housing lid by the counterrotation movement to guide the housing lid axially, so that at least a partial guided axial movement occurs during the counterrotation movement when opening the housing lid from the closed position.

According to the invention, a housing is provided, which includes a lifting means, which produces a guided axial movement of the lid, especially during opening of the housing. The guided movement prevents jamming of the housing lid during opening.

An advantageous embodiment of the housing, especially the field device housing, of the invention can provide that the securement means includes on an outer surface in the cylindrical region of the housing body a plurality of preferably equidistantly arranged, radially protruding bayonet projections, by which the housing lid can be locked by means of the rotational movement into a closed position.

Another advantageous embodiment of the housing, especially the field device housing, of the invention can provide that the securement means includes on the housing lid on an inside directed toward the outer surface of the cylindrical region when the housing lid is plugged with the lid opening over the cylindrical region a plurality of preferably equidistantly arranged, radial recesses, wherein the recesses are adapted to the protruding bayonet projections in such a manner that the recesses are guided on the bayonet projections at least during the rotational movement.

Another advantageous embodiment of the housing, especially the field device housing, of the invention can provide that the lifting means is composed of at least two parts, wherein a first part is formed in the housing body and a second part is formed in the housing lid.

Another advantageous embodiment of the housing, especially the field device housing, of the invention can provide that one of the two parts, preferably the first part, of the lifting means has at least one, preferably at least two, radially protruding, lifting contours on the outer surface of the cylindrical region of the housing body.

Another advantageous embodiment of the housing, especially the field device housing, of the invention can provide that the lifting contour has an essentially round or oval lifting contour.

An alternative embodiment of the housing, especially the field device housing, of the invention can provide that the lifting contour has an essentially triangularly shaped contour, which is embodied in such a manner that a flank directed in the opening direction of the housing body is formed as a rising flank in counterrotation movement.

Another advantageous embodiment of the housing, especially the field device housing, of the invention can provide that the other of the two parts, preferably at least the second part of the lifting means, comprises parts of the securement means, preferably of the second part of the securement means embodied on the housing lid, especially preferably the radial recesses of the second part of the securement means.

Another advantageous embodiment of the housing, especially the field device housing, of the invention can provide that a peripheral seal, especially a peripheral seal in the form of an O-ring, is provided in the cylindrical region, wherein the cylindrical region of the housing body, the housing lid and/or the peripheral seal are adapted and formed relative to one another in such a manner that at least in the closed position the peripheral seal is compressed, especially radially, by the housing lid and the cylindrical region.

The invention relates further to a field device of automation technology having a housing, especially a field device housing, according to one of the above described embodiments.

The invention will now be explained in greater detail based on the appended drawing, the figures of which show as follows:

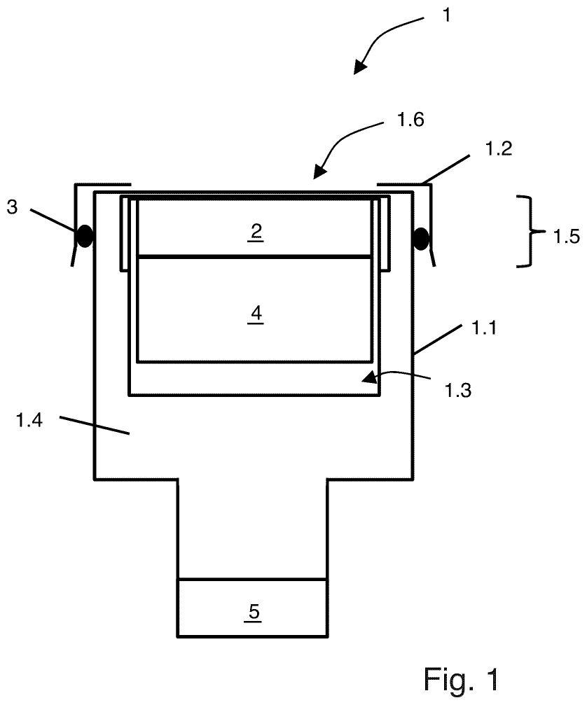

FIG. 1 a schematic view of a field device of automation technology,

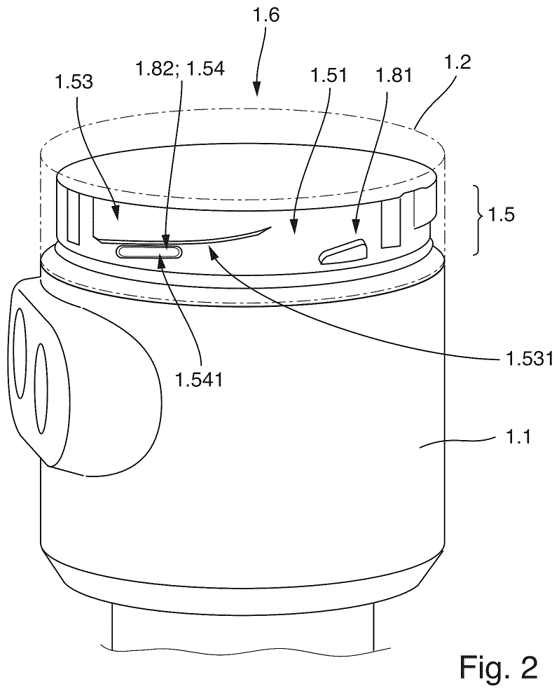

FIG. 2 a perspective view of the housing body, in the case of which the housing lid is releasably secured with the aid of the securement means,

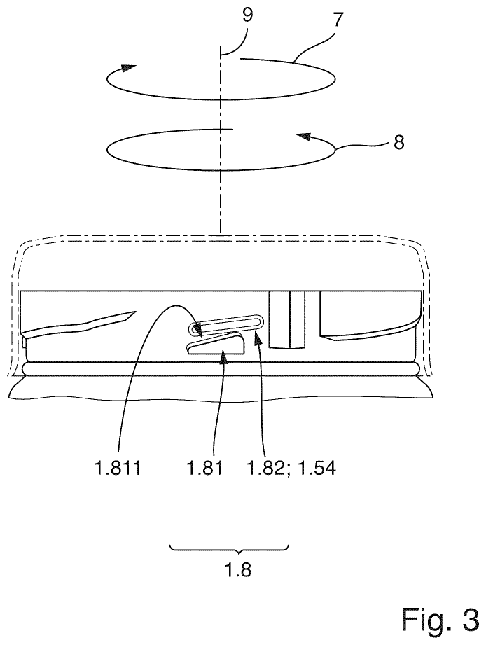

FIG. 3 an example of an embodiment of a lifting means of the invention, and

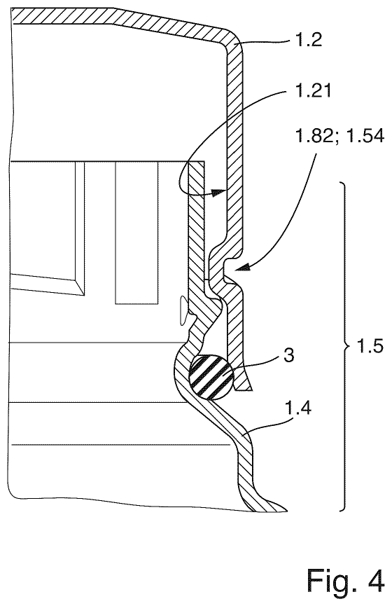

FIG. 4 a sectional view of the cylindrical region showing the housing lid attached to the housing body.

FIG. 1 shows a usual construction of a field device 1 of automation technology. Field device 1 includes a housing having a housing body 1.4 and a housing lid 1.2. Housing body 1.4 is made of sheet metal, preferably a steel sheet metal, especially preferably a stainless steel sheet metal, such as, for example, 316L stainless steel. Housing body 1.4 has an essentially muglike shape with a housing floor and a housing opening 1.6, through which an inner space 1.3 is accessible. The cross sectionally essentially round housing opening 1.6 is defined and formed by an essentially cylindrical region 1.5 of the housing body 1.4.

Housing lid 1.2 is likewise made of sheet metal, preferably a steel sheet metal, especially preferably a stainless steel sheet metal, such as, for example, 316L stainless steel. Furthermore, the housing lid 1.2 has, in turn, a traylike shape with a lid floor and a lid opening. The housing lid 1.2 and the housing body 1.4 are adapted and formed relative to one another in such a manner that the housing lid 1.2 is pluggable with its housing opening virtually head first onto the cylindrical region 1.5 of the housing body 1.4 and can be secured releasably on the housing body 1.4 by means of a securement means 1.53, 1.54 to be described in greater detail below.

The lid floor of the housing lid 1.2 can have a viewing window opening, into which a viewing window insert of a transparent material, especially a plastic, is insertable. For this, the viewing window insert can have a step shaped elevation protruding into the opening. Alternatively, a viewing window can also be integrated into the lid floor of the housing lid.

Additionally, field device 1 further includes a sensor- and/or actuator element 5 arranged on or in the housing 1.1 for setting and/or registering a process variable, as well as, located in the inner space 1.3, an electronic field device electronics 4, which, among other things, is embodied to operate the sensor- and/or actuator element 5.

In order to enable a servicing/parametering of the field device 1 and/or to display information, e.g. regarding the process variable to be registered, or set, the field device 1 can have an interaction- and/or display element 2. The interaction- and/or display element 2 can, such as shown in FIG. 1, be arranged behind the viewing window in the inner space of the housing body.

Alternatively, the interaction- and/or display element 2 can also be secured on an outside of the housing wall. When the field device 1 includes an interaction- and/or display element 2, the field device electronics 4 can also be adapted correspondingly to drive, thus to operate, the interaction- and/or display element 2.

FIG. 2 shows a perspective view of the housing body 1.4, in the case of which the housing lid 1.2 is releasably secured with the aid of the securement means 1.53, 1.54. The securement means 1.53, 1.54 has two parts in the present example of an embodiment. A first part of the securement means includes radially protruding bayonet projections 1.53, which are formed on an outer surface 1.51 of the housing body 1.4 in the cylindrical region 1.5. A second part of the securement means 1.82 comprises recesses 1.54 on the housing lid 1.2 formed radially in the direction of a rotation axis 9. Recesses 1.54 and bayonet projections 1.53 are adapted and formed relative to one another in such a manner that the recesses 1.54 run along and are correspondingly guided on a flank 1.531 of the protruding bayonet projections 1.53 directed away from the housing opening 1.6 in case of a rotational movement 7 around the rotation axis 9, by which the housing lid is brought into a closed position on the housing body.

The recesses 1.54 formed radially in the direction of the rotation axis 9 on the housing lid have preferably an oval or rectangular contour with rounded corners. Both the radially protruding bayonet projections 1.53 as well as also the recesses 1.54 can be manufactured, for example, by stamping of the sheet metal of the housing body 1.4 and housing lid 1.2.

With securement means 1.53, 1.54, the housing lid 1.2 can be locked by means of the rotational movement. In the example of an embodiment, three protruding bayonet projections are arranged distributed over the periphery of the cylindrical opening of the housing body. Other options provide, however, that only two or more than three protruding bayonet projections are present. Then, of course, a corresponding number of radially formed recesses 1.54 are located on the housing lid 1.2. Preferably, the protruding bayonet projections 1.53 are arranged distributed equidistantly relative to one another over the periphery on the outer surface 1.51 of the cylindrical region 1.5. The protruding bayonet projections are each embodied in such a manner that the flank 1.531 of the bayonet projection 1.53 protruding far from the opening of the housing body is formed receding in rotational movement 7. The recesses 1.54 are preferably likewise arranged distributed equidistantly from one another on an inner surface 1.21 of the housing lid. Furthermore, a flank of each recess directed toward housing opening can likewise be formed receding in rotational movement, such that the two flanks run along one another during opening and closing of the housing lid.

According to the invention, housing 1.1 includes, moreover, a lifting means 1.8. FIG. 3 shows an example of an embodiment of such a lifting means 1.8. By lifting means 1.8, the housing lid 1.2 is guided axially at least during counterrotation movement 8 for opening of housing, such that tilting of the housing lid 1.2 and, associated therewith, jamming are prevented. The lifting means 1.8 as shown is formed of at least two parts.

A first part 1.81 of the lifting means is formed in the housing body 1.4 in the cylindrical region 1.5. The first part of the lifting means 1.81 comprises in the present example of an embodiment a plurality of radially protruding, lifting contours 1.81. Preferably, the radially protruding, lifting contours 1.81 are arranged distributed equidistantly over the periphery relative to one another on the outer surface 1.51 of the cylindrical region 1.5. The lifting contours 1.81 can be manufactured, for example, by stamping of the sheet metal of the housing body 1.4. As regards outer contour, the radially protruding, lifting contours 1.81 can have, for example, an essentially round or oval shape. Proved especially advantageous is an essentially triangularly shaped lifting contour 1.81, such as shown in FIG. 3. The lifting contour 1.8 is, in such case, formed preferably in such a manner that a flank directed in the opening direction of the housing body 1.811 is formed as a rising flank in the case of counterrotation movement 8.

A second part of the lifting means 1.82 is embodied in the housing lid 1.2. The second part of the lifting means 1.82 comprises a plurality of recesses 1.82 formed radially in the housing lid in the direction of the rotation axis 9. Such are preferably likewise arranged distributed equidistantly relative to one another on an inner surface of the housing lid. The recesses can likewise be made by stamping. Especially serving as second part of the lifting means 1.82 is a part of the securement means serving likewise for securing the housing lid 1.2 on the housing body 1.4. In the illustrated example of an embodiment, the recesses 1.54 formed radially in the direction of the rotation axis 9 in the housing lid serve as second part of the lifting means 1.82. In such case, the housing opening directed recess flank 1.541, which can be formed receding in rotational movement, serves also as corresponding counterflank, such that the two flanks run along one another during opening and closing of the housing lid. Another option is, however, that the second part of the lifting means 1.82 is embodied as a separate contour in the housing lid.

In order to assure a safe closing of the housing lid 1.2, furthermore, a peripheral seal can, such as shown in the sectional view in FIG. 3, be provided in the cylindrical region 1.5, where the housing lid 1.2 sits on the housing body 1.4. In order to hold the peripheral seal 3, the housing lid 1.2 can have in the cylindrical region 1.5 a peripheral groove, into which the peripheral seal 3 is insertable, or inserted. Housing lid 1.2 and housing body 1.4 are adapted and formed in the cylindrical region 1.5 in such a manner relative to one another that during closing the housing lid compresses, especially radially compresses (radial seal seat), the peripheral seal 3 between the housing body 1.4 and the housing lid 1.2. Furthermore, the housing lid 1.2 can be formed in such a manner that a diameter of the housing lid 1.2 decreases from the lid opening toward the lid floor, at least in a subregion, such that an easier plugging of the housing lid 1.2 on the housing body 1.4 as well as a subsequent locking by the above described securement means 1.53,1.54 are possible.

### LIST OF REFERENCE CHARACTERS

1 field device
1.1 field device housing
1.2 lid of the field device housing
1.21 inside of the lid
1.3 interior of the field device housing
1.4 housing body
1.5 cylindrical region
1.51 outer surface, or outer contour, of the cylindrical region
1.53 bayonet protrusion on the housing body
1.531 flank of the bayonet protrusion
1.54 recesses on the housing lid
1.541 flank of a recess
1.6 opening of the field device housing
1.8 lifting means
1.81 first part of the lifting means, or lifting contour
1.811 flank of the first part of the lifting means
1.82. second part of the lifting means
2 interaction- and/or display element
3 peripheral sealing means
4 electronics, electronic circuit
5 sensor- and/or actuator element
6 connecting element
7 rotational movement for closing the housing lid
8 counterrotation movement for opening the housing lid
9 rotation axis

1-10. (canceled)

11. A housing comprising a housing body and a housing lid,
wherein the housing body has a cuplike shape and defines an inner volume accessible through an opening of the housing body, wherein the housing body includes an essentially cylindrical region, which adjoins and defines the opening and on which the housing lid is placeable to close the inner volume of the housing body;
wherein the housing lid has a traylike shape with a lid floor and a lid opening, and wherein the housing body and the housing lid are conformed to one another and embodied such that the housing lid can be placed over or on the cylindrical region such that the housing lid covers the opening;
wherein at least one of the housing lid and the cylindrical region of the housing body includes a securement means, wherein the securement means is configured such that:
the housing lid can be brought by rotational movement into a closed position on the housing body and can be locked by the securement means in the closed position, and
the housing lid can be released from the housing body by a counterrotation movement;
wherein at least one of the housing lid and the cylindrical region of the housing body includes a lifting means, wherein the lifting means is configured to at least guide the housing lid axially when opening the housing lid by the counterrotation movement such that at least a partial guided axial movement occurs during the counterrotation movement when opening the housing lid from the closed position.

12. The housing of claim 11, wherein the housing body and the housing lid are formed of metal.

13. The housing of claim 11, wherein the housing body and the housing lid are formed of steel.

14. The housing of claim 11, wherein the housing body and the housing lid are formed of stainless steel.

15. The housing as claimed in claim 11, wherein the securement means includes a plurality of radially protruding bayonet projections on an outer surface in the cylindrical region of the housing body, by which the housing lid can be locked into the closed position by rotational movement.

16. The housing of claim 15, wherein the bayonet projections are equidistantly arranged.

17. The housing as claimed in claim 15, wherein the securement means includes a plurality of radial recesses on the housing lid arranged on an inner surface facing toward the outer surface of the cylindrical region when the housing lid is placed with the lid opening over the cylindrical region, wherein the recesses are conformed to the protruding bayonet projections such that the recesses are guided on the bayonet projections at least during the rotational movement.

18. The housing of claim 17, wherein the radial recesses are equidistantly arranged.

19. The housing as claimed in claim 18, wherein the lifting means includes at least two regions, wherein a first region is embodied in the housing body and a second region is formed in the housing lid.

20. The housing as claimed in claim 19, wherein one of the two regions of the lifting means includes at least one radially protruding lifting contour on the outer surface of the cylindrical region of the housing body.

21. The housing as claimed in claim 20, wherein at least one subregion of the two regions comprises a portion of the securement means, wherein the subregion is on the second region of the lifting means embodied on the housing lid.

22. The housing as claimed in claim 20, wherein the at least one lifting contour has an essentially round or oval lifting contour.

23. The housing as claimed in claim 20, wherein the at least one lifting contour has an essentially triangularly shaped contour, which is embodied such that an edge directed in an opening direction of the housing body is embodied as a lifting edge in counterrotation movement.

24. The housing of claim 20, wherein the first region of the lifting means includes at least two radially protruding lifting contours.

25. The housing as claimed in claim 11, wherein a peripheral seal is provided in the cylindrical region, wherein the cylindrical region of the housing body, the housing lid and/or the peripheral seal are embodied relative to one another such that at least in the closed position the peripheral seal is radially compressed by the housing lid and the cylindrical region.

26. The housing of claim 25, wherein the peripheral seal is in the form of an O-ring.

27. A field device of automation technology having a housing as claimed in claim 11.
